(19) United States
(12) Patent Application Publication
(10) Pub. No.: US 2014/0106698 A1
(43) Pub. Date: Apr. 17, 2014

(54) VARIABLE BAND PASS FILTER DEVICE

(71) Applicant: FUJITSU LIMITED, Kawasaki-shi (JP)

(72) Inventors: Xiaoyu Mi, Akashi (JP); OSAMU TOYODA, Akashi (JP); Satoshi UEDA, Kakogawa (JP)

(73) Assignee: FUJITSU LIMITED, Kawasaki-shi (JP)

(21) Appl. No.: 14/132,895

(22) Filed: Dec. 18, 2013

Related U.S. Application Data
(63) Continuation of application No. PCT/JP2011/003910, filed on Jul. 7, 2011.

(51) Int. Cl. H03H 7/01; H04B 1/10; H03H 7/12

(52) U.S. Cl. CPC H03H 7/0123; H03H 7/12; H04B 1/10
USPC 455/307; 333/174

(57) ABSTRACT

A variable filter device has: a first series arm which is serially connected to a signal line, includes a variable capacitance and an inductance, and constitutes a series resonator; first and second parallel arms, which are connected between the signal line and the ground on both sides of the first series arm, each of which includes a variable capacitance and an inductance, and constitutes a grounded series resonator. The first series arm defines the center frequency of the pass band, and the first and second parallel arms define attenuation poles sandwiching the pass band.

### CROSS REFERENCE TO RELATED APPLICATIONS

This application is a continuation application of the prior International Application No. PCT/JP2011/003910, filed on Jul. 7, 2011, the entire contents of which are incorporated herein by reference.

### FIELD

The invention relates to a variable filter device for use for band pass of a high-frequency signal and to a communication device that uses the variable filter device.

### BRIEF DESCRIPTION OF DRAWINGS

FIGS. 1A to 1E are a block diagram of a communication device, and a block diagram of a variable filter, according to an embodiment, and equivalent circuit diagrams illustrating examples of arm SA or PA, and a graph schematically illustrating characteristics of a filter.

FIGS. 2A and 2B are equivalent circuit diagrams illustrating a first element and a second element of a variable filter according to Embodiment 1, and FIGS. 2C and 2D illustrate equivalent circuit diagrams of variable filters formed by combining the first and second elements.

FIGS. 3A and 3B are graphs illustrating examples of characteristics of variable filters constructed according to Embodiment 1.

FIG. 4A is an equivalent circuit diagram of a variable filter according to Embodiment 2 in which series resonators of the variable filter illustrated in FIG. 2D are replaced with distributed constant lines, and FIGS. 4B and 4C are sectional views illustrating structure examples of the distributed constant line.

FIG. 5A is a sectional view illustrating an example of a variable capacitance utilizing MEMS, FIG. 5B is an equivalent circuit diagram of a circuit utilizing a varactor diode as a variable capacitance, and FIG. 5C is an equivalent circuit diagram of a circuit utilizing a circuit including capacitor array and switches as a variable capacitance.

FIGS. 6A to 6D are equivalent circuit diagrams for illustrating band pass filters according to the related art and a graph illustrating the characteristics.

FIG. 7 is an equivalent circuit diagram of a frequency variable filter according to the related art.

### BACKGROUND

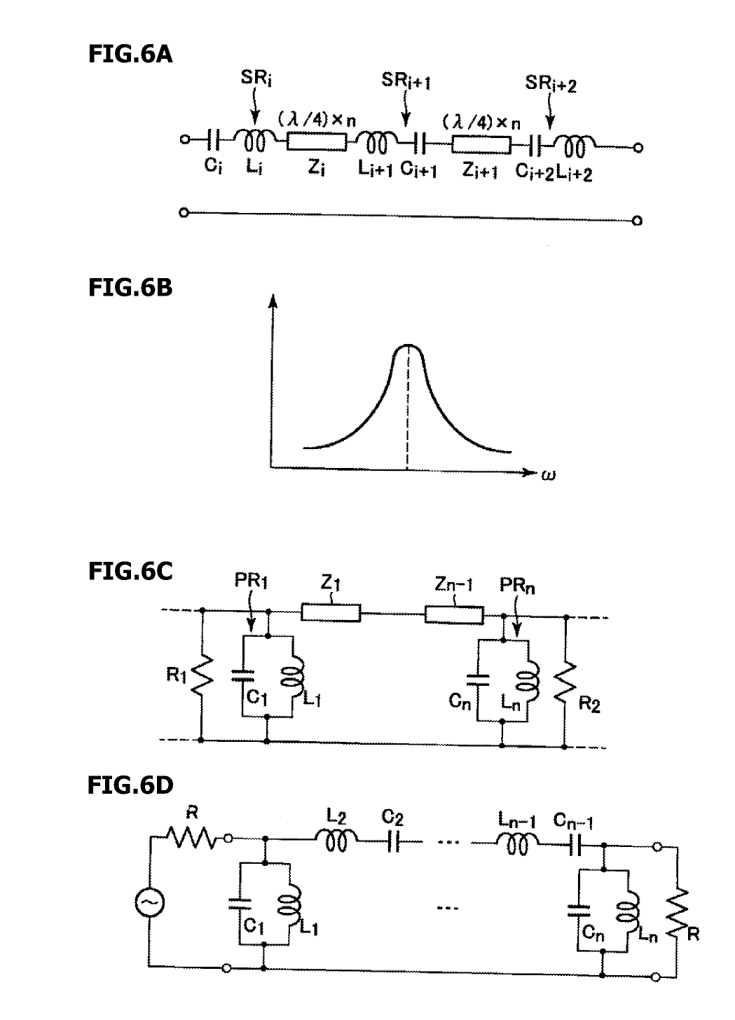

FIGS. 6A to 6D are equivalent circuit diagrams for illustrating related-art band pass filters used for passing a frequency band, and a graph illustrating the characteristics. In high-frequency communication, there is a usage of a band pass filter for selectively passing only signals of a specific frequency band. As the characteristics of a band pass filter, a center frequency of the pass band and a pass bandwidth are first determined.

FIG. 6A illustrates a band pass filter in which a plurality of series resonators are connected in series to or in a signal line. Series resonators SRᵢ, SRᵢ₊₁, SRᵢ₊₂, . . . determining pass bands are connected in series to or in the signal line, via coupling portions Zᵢ, Zᵢ₊₁, . . . each having an electrical length of (λ/4)×n. Each series resonator SR includes a series connection of a capacitance C and a inductance L, and has transmission characteristics as schematically illustrated in FIG. 6B. When plural stages of series resonators are connected in series, the characteristics thereof become multiplications of the respective characteristics. When series resonators having the same center frequency and the same pass bandwidth are connected in series, the center frequency and the pass bandwidth remain unchanged, and a sharpness of the characteristics increases. The pass loss, however, also increases.

FIG. 6C illustrates a structure in which a plurality of parallel resonators PR₁ to PRₙ are connected in parallel to a signal line (between the signal line and ground) via coupling portions Z₁ to Zₙ₋₁ each having an electrical length of (λ/4)×n. The parallel resonator connected in parallel to the signal line also has characteristics as illustrated in FIG. 6B. FIG. 6D illustrates a ladder structure in which a plurality of parallel resonators and a plurality of series resonator are alternately connected. The circuits in FIGS. 6C and 6D exhibit the characteristics of the band pass filter, in which the steepness is determined by the Q values and the number of stages similar to the series resonator of FIG. 6A. Incidentally, a resonator having an electrical length of (λ/2) satisfies the condition of (λ/4)×n, and can become a coupling portion. In the case of the ladder structure, the parallel resonators connected in parallel to the signal line constitute coupling portions for the series resonators that are connected in series to the signal line, and the series resonators connected in series to the signal line constitute coupling portions for the parallel resonators connected in parallel to the signal line.

In recent years, the market of mobile communication represented by cellular phone is expanding, and higher performance services are being developed. The frequency bands for mobile communication tends to gradually shift to higher frequency bands of gigahertz (GHz) or higher and there is a tendency of multi-channel communication. Furthermore, the possibility of future introduction of software-defined-radio (SDR) in which communication system is changed by software is being enthusiastically discussed. In order to realize the software-defined-radio, wide adjustable range for circuit characteristics is desired.

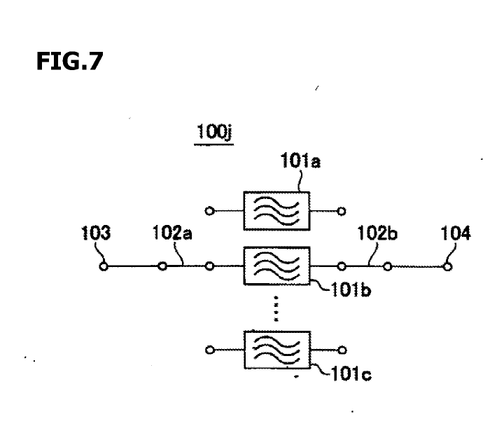

FIG. 7 is a circuit diagram illustrating a related-art frequency variable filter 100j. The frequency variable filter 100j has a plurality of channel filters 101a, 101b, 101c, . . . and a pair of switches 102a and 102b. By changing the connection of the switches 102a and 102b, one of the channel filters 101a, 101b, 101c, . . . is selected, to change the frequency band. The high-frequency signal input from an input terminal 103 is subjected to filtering by a selected channel filter 101, and is output from an output terminal 104.

The frequency variable filter 100j has as many channel filters as the number of channels. When the number of channels is increased, the number of channel filters increases, and the structure becomes complicated. The size and the cost also increase. The feasibility of the software-defined-radio is low.

In recent years, small-size frequency variable filters that use MEMS (micro electro mechanical system) are drawing attention. A MEMS device (micro-machine device) that utilizes MEMS technology is able to obtain a high Q (quality factor), and can be applied to a variable filter of a high frequency band (e.g., Japanese Patent Laid-Open Publication No. 2008-278147, Japanese Patent Laid-Open Publication No. 2010-220139, D. Peroulis, et al., “Tunable Lumped Components with Applications to Reconfigurable MEMS Filters”, 2001 IEEE MTT-S Digest, pp. 341-344, E. Fourn et al., “MEMS Switchable Interdigital Coplanar Filter”, IEEE Trans. Microwave Theory Tech., vol. 51, NO. 1 pp. 320-324, January 2003, and A. A. Tamijani, et al., “Miniature and Tunable Filters Using MEMS Capacitors”, IEEE Trans. Microwave Theory Tech., vol. 51, No. 7, pp. 1878-1885, July 2003). Furthermore, since MEMS devices are small in size and can be low in loss, the devices are often used in CPW (coplanar waveguide) distributed constant resonators.

A filter having a structure in which a plurality of variable capacitors made of MEMS devices are astride a three-stage distributed constant line is also disclosed (e.g., A. A. Tamijani, et al., “Miniature and Tunable Filters Using MEMS Capacitors”, IEEE Trans. Microwave Theory Tech., vol. 51, No. 7, pp. 1878-1885, July 2003). In this filter, a control voltage Vb is applied to a drive electrode of an MEMS device to displace a variable capacitor, changing the gap from the distributed constant line, and changing the electrostatic capacitance. Changes in electrostatic capacitance change the pass band of the filter. The related-art filter is able to vary the center frequency of the pass band, but cannot greatly change the pass bandwidth.

With regard to a band pass filter, steepness of the pass band is often demanded as well as the center frequency and bandwidth of the pass band. By heightening the Q value of the resonator and increasing the number of stages of the resonator, the steepness can be enhanced. However, if the number of stages is increased, the pass loss increases so that the band pass filter often becomes unpractical. In pursuit of obtaining a wide frequency variable range, the structure is likely to become complicated.

### SUMMARY

According to one aspect, a variable filter device includes:

ground conductor serving as earth and a signal line in combination with the ground conductor;

a first series arm forming part of the signal line, and constituting a variable series resonator having a variable resonance frequency; and

first and second parallel arms, connected between the signal line and the ground conductor at both sides of the first series arm, each of the first and second parallel arms constituting a variable series resonator having a variable resonance frequency;

wherein each of the variable series resonators includes a series connection of a variable capacitance and an inductance, or a variable distributed constant line.

The object and advantages of the invention will be realized and attained by means of the elements and combinations particularly pointed out in the claims.

It is to be understood that both the foregoing general description and the following detailed description are exemplary and are not restrictive of the invention, as claimed.

### DESCRIPTION OF EMBODIMENTS

The following feature can be provided in this embodiment, and similarly in the following embodiments:

the pass bandwidth can be adjusted as well as the center frequency of the pass band.

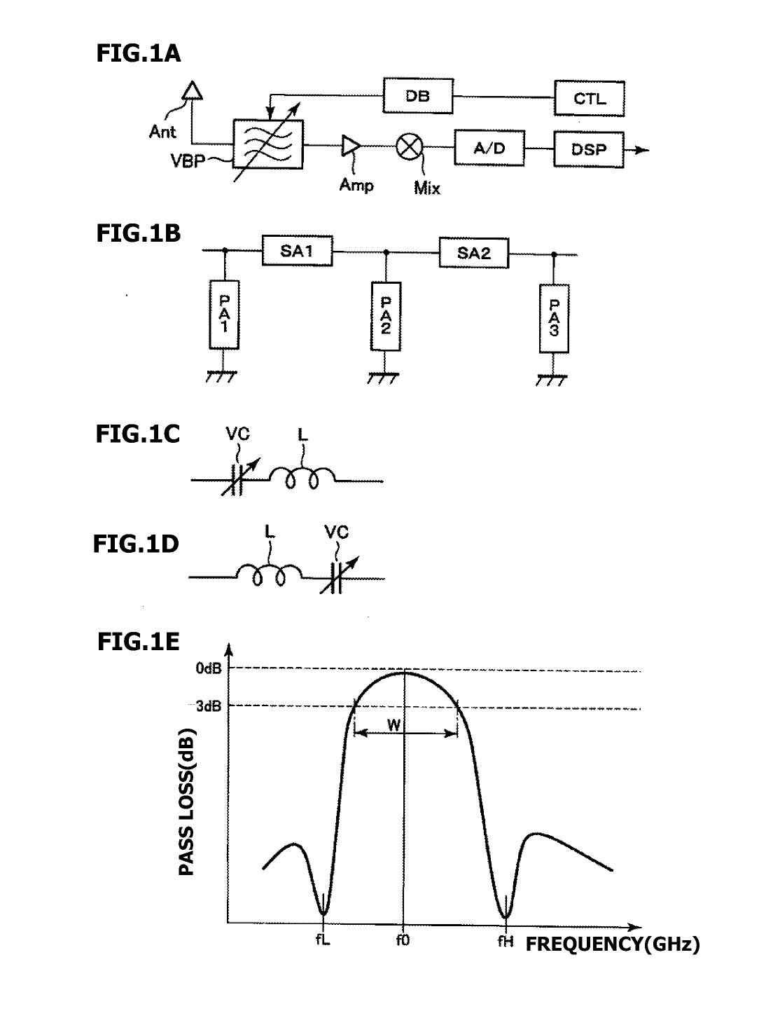

FIG. 1A schematically illustrates a communication device according to an embodiment. A control circuit CTL selects parameters from a database DB, according to the center frequency and bandwidth of a receiving band, and controls a variable band pass filter VBP. A high-frequency signal input from an antenna Ant, is filtered to select a desired frequency band in the variable band pass filter VBP, and is amplified in an amplifier Amp. The amplified high-frequency signal is converted in frequency by a mixer Mix, and is ND converted from analog signals into digital signals in an analog/digital converter ND, and then is subjected to signal processing in a digital signal processor DSP. The obtained digital signal is utilized for various purposes.

FIG. 1B is a block diagram of a variable filter for use in the variable band pass filter VBP. Series arms SA1, SA2, . . . are connected in series to (that is, in series in) a signal line. Parallel arms PA1, PA2, PA3, . . . are connected between the both ends of respective series arms SA and the ground. The parallel arms PA1 and PA2 are connected to the two ends of the series arm SA1, and the parallel arms PA2 and PA3 are connected to the two ends of the series arm SA2. Each of the series arms SA1, SA2, . . . includes a series connection of a variable capacitance VC and an inductance L, for example, as illustrated in FIG. 1C or FIG. 1D, and constitutes a series resonator. Each series resonator has a transmission characteristic as illustrated in FIG. 6B. By changing the variable capacitance VC, the center frequency of the pass band can be changed. The series resonators in FIG. 1C and FIG. 1D are different only in that the order of the connection sequence of the variable capacitance and the inductance is reversed, and are equivalent in the function of circuit.

Each of the parallel arms PA1, PA2, PA3 includes a series connection of a variable capacitance VC and an inductance L as illustrated in FIG. 1C or FIG. 1D, and constitutes a grounded series resonator. That is, the parallel arms PA1, PA2, PA3, . . . connect the signal line to the ground at specific frequencies and thus have a function of forming attenuation poles.

FIG. 1E illustrates characteristics of a basic filter structure constituted of one series arm SA and two parallel arms PA connected at the two ends of the series arm. A pass band with a center frequency f₀ is formed by the series arm SA, and attenuation poles are formed above and below the pass band, i.e. at frequencies f_{H}, f_{L}, by the parallel arms PA. Hereinafter, the attenuation poles will sometimes be denoted as f_{H}, f_{L}. By changing the variable capacitances VC of the parallel arms PA, the frequencies of the attenuation poles f_{H}, f_{L} can be changed. By changing the attenuation poles f_{H}, f_{L}, the bandwidth W of the pass band can be variably set.

As illustrated in FIG. 1B, an arbitrary number of series arms SA can be connected in series to or in the signal line, and parallel arms PA can be connected between the two ends or sides of the respective series arms and the ground. The number of series arms may be one. In this case, the series arms SA2 and the parallel arm PA3 in FIG. 1B are dispensed with. When a plurality of series arms SA are connected in series to the signal line, the frequency selectivity of the band pass filter is enhanced. With respect to the plurality of series arms, the parallel arms PA between the adjacent series arms form coupling portions of (λ/4)×2=(λ/2). With respect to the plurality of parallel arms PA, the series arms SA between the adjacent parallel arms also form coupling portions of (λ/4)×2=(λ/2). By connecting, at the both sides of each series arm, parallel arms each including a grounded series resonator, the attenuation poles f_{H}, f_{L} can be formed above and below the pass frequency band. This makes it possible to control the pass bandwidth and provide steepness.

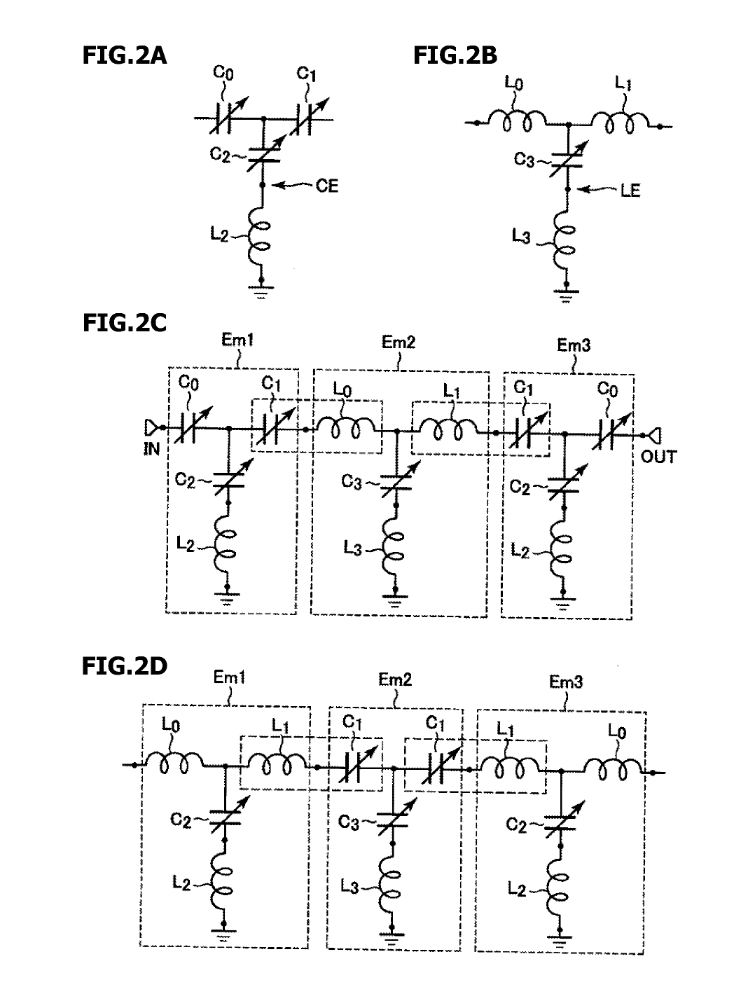

FIGS. 2A and 2B illustrate two elements for use in the filter according to Embodiment 1. FIG. 2A illustrates a capacitive element CE in which two variable capacitors C₀ and C₁ are connected in series to or in the signal line, and a series connection of a variable capacitance C₂ and an inductance L₂ is connected as a parallel arm between the ground and the interconnecting point between the variable capacitors C₀ and C₁. The variable capacitances C₀ and C₁ of the series arm are used for setting the resonance frequency. Capacitances C₀ and C₁ are variable. The series connection of the variable capacitance C₂ and inductance L₂ constitutes a series resonator, and forms a parallel arm with respect to the signal line, defining attenuation pole.

FIG. 2B illustrates an inductive element LE in which two inductances L₀ and L₁ are connected in series to or in the signal line and a series connection of a variable capacitance C₃ and an inductance L₃ is connected as a parallel arm between the ground and an interconnecting point between the inductances L₀ and L₁. The inductances L₀ and L₁, for example, have equal values, but may also have different values. The series connection of the variable capacitance C₃ and the inductance L₃ constitutes a series resonator, and defines a parallel arm that determines attenuation pole with respect to the signal line.

By alternately connecting elements CE and LE as illustrated in FIGS. 2A and 2B, a band pass filter can be constructed. The order and number of elements CE and LE can arbitrarily be selected according to purpose. By alternately connecting capacitive elements CE and inductive elements LE, a plurality of LC series resonators can be formed on the signal line, with coupling portions being provided by the LC parallel resonators connected to the ground.

FIG. 2C illustrates a filter in which three elements Em1, Em2, Em3 are connected between an input terminal IN and an output terminal OUT. The elements Em1, Em2 and Em3 are formed of a capacitive element CE, an inductive element LE and a capacitive element CE, respectively. The variable capacitances C₀ and C₁ of the capacitive element Em3 are reversed in the left right direction, compared to the capacitive element Em1. The output side variable capacitance C₁ of the element Em1 and the input side inductance L₀ of the element Em2 constitute a series resonator, and the output side inductance L₁ of the element Em2 and the input side variable capacitance C₁ of the element Em3 constitute another series resonator.

When the inductances L₀ and L₁ and the two capacitances C₁ of the two series resonators are equal, two stages of band pass filter having equal center frequency are formed, and the pass band is determined. For example, the pass band with a center frequency f₀ is determined. The series resonator of C₂ and L₂ included in the parallel arm of each of the elements Em1 and Em3 determines one attenuation pole, for example f_{H}, and the series resonator of C₃ and L₃ included in the parallel arm of the element Em2 determines the other attenuation pole, for example f_{L}. By appropriately disposing the attenuation poles f_{H} and f_{L} with respect to the center frequency f₀, a desired bandwidth is obtained.

FIG. 2D illustrates a filter in which three elements Em1, Em2 and Em3 are connected between an input terminal IN and an output terminal OUT. The element Em1, Em2 and Em3 are formed by an inductive element LE, a capacitive element CE and an inductive element LE, respectively. As in FIG. 2C, two LC series resonators whose center frequencies are equal can be connected in series to the signal line. The parallel arms constitute two L₂C₂ series resonators and one L₃C₃ series resonator. Selection of L₂C₂ and L₃C₃ is free. In the case where a high-frequency side steepness is desired, attenuation pole on the higher frequency side f_{H} may be determined by L₂C₂, while the lower frequency attenuation pole f_{L} is determined by L₃C₃.

Incidentally, the number of stages, i.e. the number of elements, in the filter is not limited to three. It may be two, or four or more. The order of L and C in each parallel arm may be interchanged. The outer L or C in the outermost series arm in the signal line can be omitted. For example, the number of stages of the variable band pass filter may be set to two to ten, and the inductance L may be set to 0.2 nH to 30 nH, and the capacitance C may be set to 0.2 pF to 100 pF.

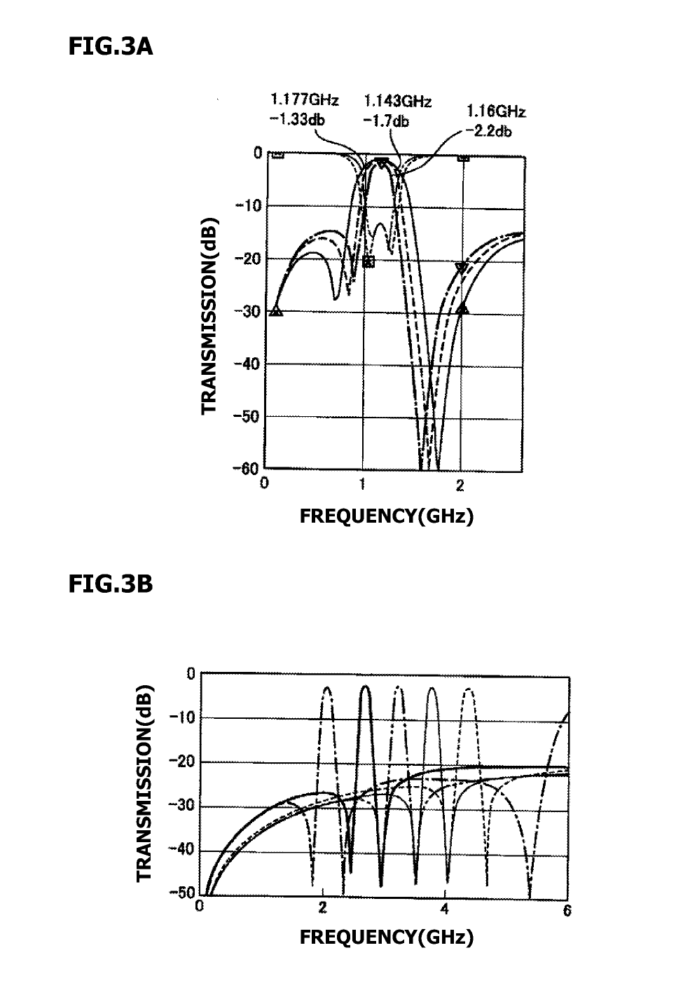

FIG. 3A is a graph illustrating changes in the pass bandwidth that occur when the frequencies of the attenuation poles f_{H} and f_{L} are changed by adjusting the variable capacitances C₂ and C₃ of the series resonators determining attenuation poles in the structure in FIG. 2C.

FIG. 3B is a graph illustrating changes in the pass characteristics of the variable band pass filter when the capacitances of the variable capacitances C₀, C₁, C₂ and C₃ are changed in the structure in FIG. 2C. The horizontal axis represents the frequency in GHz, and the vertical axis represents the transmission in the unit of dB. In one example, the center frequency of the pass band changes from about 4.4 GHz to about 2.06 GHz.

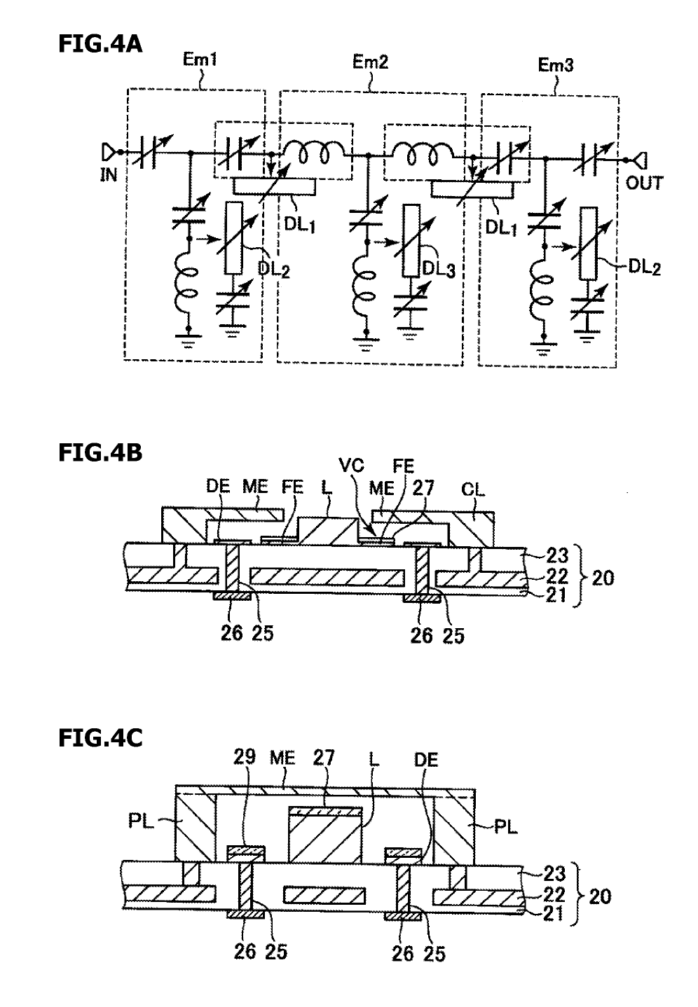

FIG. 4A illustrates a structure in which the LC series resonators in the structure in FIG. 2C are replaced with distributed constant lines. Two LC series resonators of series arms are replaced with two variable distributed constant lines DL1, and three LC series resonators of the parallel arms are also replaced with three distributed constant lines DL2 and DL3. Specifically, the parallel arms of LC series resonators of the elements Em1 and Em3 are replaced by variable distributed constant lines DL2 (+variable capacitances), and the parallel arm of LC series resonator of the element Em2 is replaced with a variable distributed constant line DL3 (+a variable capacitance). A distributed constant line is able to form and constitute a distributed capacitance on a transmission line.

FIG. 4B is a sectional view illustrating a structure example of a distributed capacitance line. A transmission line L made, for example, of copper, is formed on a dielectric substrate 20. A bottom portion of the transmission line L is widened or expanded to both sides, to form a wider lower portion than an upper portion. Above the expanded portions, spaces for housing movable electrodes ME of variable capacitors VC are secured. The expanded portions of the transmission line L serve as fixed electrodes FE of the variable capacitors VC. An arbitrary number of variable capacitances may be formed along the line. An insulation layer 27 may be formed on an upper surface of each expanded portion, providing function of preventing short-circuit (insulation) and improving effective permittivity. The insulation layers may be formed from an inorganic insulation material or be formed from an organic insulation material. Depending on cases, the insulation layers may be dispensed with. This structure can be created, for example, by two plating processes using resist pattern having opening that defines a contour.

A movable electrode ME is supported by a flexible cantilever structure CL made, for example, of copper, which is formed on the dielectric substrate 20. It can also be considered that a distal end of each flexible cantilever CL constitutes a movable electrode ME. This structure can be created, for example, by plating process that uses resist pattern having opening of three dimensional shape. This structure may also be formed by performing two plating processes that use resist pattern having opening that defines a contour. A drive electrode DE is formed on the dielectric substrate 20, below a movable portion of each flexible cantilever CL. The drive electrodes can be created, for example, simultaneously with the expanded portions of the transmission line. The drive electrodes may also be formed from a metal material made separately from the transmission line, in a separate process. In this case, a separate process of sputtering or the like may be used.

The dielectric substrate 20 has a structure in which an electro-conductive metal layer 22 formed from Ag or the like and serving as a grounded layer is formed on a ceramics layer 21, and another ceramics layer 23 is formed thereon. This structure can be formed by stacking a ceramics green sheet layer, an electro-conductive layer (wiring layer) and a ceramics green sheet layer while registering them in position, and then sintering them. In the ceramics layers, there are formed metal via members for connection between metal layers and high-impedance resistance members for transmitting dc bias, while preventing leakage of high-frequency signals to a DC drive path. The permittivity of the ceramics can be selected in the range of about 3 to about 100. Electro-conducting via members are buried below support portions of the flexible cantilevers CL, that is, below the drive electrodes. The flexible cantilevers CL are connected to the grounded layer 22, and the drive electrodes DE are connected to terminals 26 formed on a rear surface of the dielectric substrate 20, through electro-conductors 25 penetrating through the ceramics layer. Pads for output and input of an RF signal and a DC drive signal may be formed on the rear surface of the dielectric substrate. These pads are connected to structural bodies formed on the front surface of the substrate or to wiring formed in the substrate, through via metal members or high-impedance resistance members formed in the substrate.

In the structure of FIG. 4B, the movable electrodes ME are connected to the grounded layer. A dc (direct-current) voltage of about 10 V to 100 V is applied to the drive electrodes DE. Due to electrostatic attractive force, the movable electrodes ME are attracted toward the fixed electrodes FE. The electrical length of the transmission line L is determined by the variable capacitance of the variable capacitors VC and the circuit constant of the transmission line L. If the variable capacitance is made larger, the electrical length can be made longer.

FIG. 4C illustrates an example of a variable capacitor that has a beam structure (supported or fixed at both ends). A pair of electro-conductive pillars (support portions) PL are formed on the dielectric substrate 20, and a movable electrode ME of a flexible beam structure is formed bridging the pillars PL. A transmission line L is disposed on the dielectric substrate 20 below the movable electrode ME. Drive electrodes DE are disposed on the dielectric substrate 20, at both sides of the transmission line L. Dielectric layers 27′ and 29 are formed on the transmission line L and the drive electrodes DE. The dielectric layers 27′ and 29 may be dispensed with. The structure of the dielectric substrate 20 is substantially similar to the structure in FIG. 4B.

The variable capacitance constituting a band pass filter can be realized in various forms, for example, in the form of MEMS capacitor, varactor diode, capacitor array and a group of switches, etc.

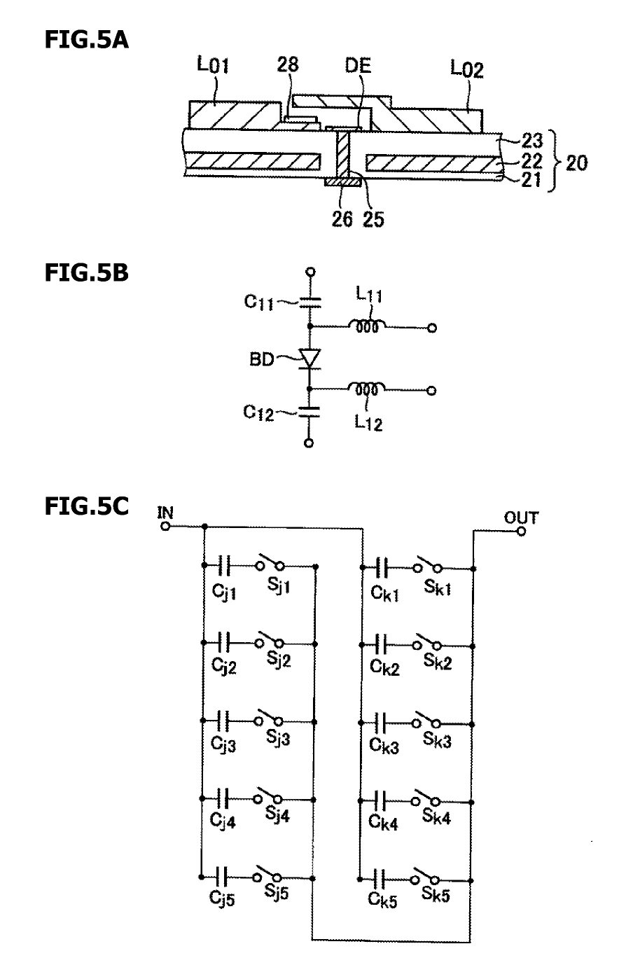

FIG. 5A is a sectional view illustrating a structure of a variable capacitor VC connected in a signal way. A lower electrode line L01 that has an expanded or widened lower portion and an upper electrode line L02 that has an expanded or widened upper flexible portion are formed on a dielectric substrate 20, and have their expanded or widened portions overlap with each other. A variable capacitor is thus formed. A drive electrode DE is formed below the expanded upper portion of the upper electrode line L02. An insulation film 28 is formed on an upper surface of the expanded electrode of the lower electrode line L01. The drive electrode DE is connected to a terminal 26 on a reverse surface of the dielectric substrate 20, via a conductor 25 penetrating through the substrate 20. The expanded upper portion of the upper electrode line L02 has a flexible cantilever structure, and is displaced downward when a dc voltage is applied to the drive electrode DE to generate electrostatic attractive force.

FIG. 5B illustrates a variable capacitor that uses a varactor. A varactor diode BD changes the capacitance under reverse bias. Inductors L11 and L12 for applying reverse bias are connected to a positive electrode and a negative electrode of the varactor BD. Capacitors C11 and C12 for passing a high-frequency signal through the varactor and blocking dc bias voltage are connected to the positive electrode and the negative electrode of the varactor BD.

FIG. 5C illustrates a variable capacitance that uses a capacitor array and group of switches. Capacitors C and switches S are connected in series to respectively form switchable capacitors. Input terminals of capacitors Cj1 to Cj5 and Ck1 to Ck5 are connected to an input terminal IN, and output terminals of switches Sj1 to Sj5 and Sk1 to Sk5 are connected to an output terminal OUT. When arbitrary switches S are closed (connected), corresponding ones of the capacitors are connected in parallel between the input terminal IN and the output terminal OUT. The value of capacitance and the number of capacitors can be freely selected.

While the invention has been described above with reference to embodiments, the invention is not limited to these embodiments. For example, it is possible to use a glass epoxy substrate instead of the ceramics substrate. Furthermore, both sides or one side of the filter of any of the foregoing embodiments may be connected with a filter of different kind (a band pass filter, a low pass filter, a high pass filter, a notch filter, etc.).

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What we claim are:

1. A variable filter device comprising:
ground conductor serving as earth and a signal line in combination with the ground conductor;
a first series arm forming part of the signal line, and constituting a variable series resonator having a variable resonance frequency; and
first and second parallel arms, connected between the signal line and the ground at both sides of the first series arm, each of the first and second parallel arms constituting a variable series resonator having a variable resonance frequency;
wherein each of the variable series resonators includes a series connection of a variable capacitance and an inductance, or a variable distributed constant line.

2. The variable filter device according to claim 1, wherein the first series arm determines a center frequency of a pass band, and the first and second parallel arms determine attenuation poles sandwiching the pass band.

3. The variable filter device according to claim 1, wherein each of the first series arm and the first and second parallel arms includes a series connection of a variable capacitance and an inductance.

4. The variable filter device according to claim 3, further comprising:
a second series arm forming part of the signal line, connected in series to said first series arm via the second or the third parallel arm, including a variable capacitance and an inductance, constituting a variable series resonator having a variable resonance frequency; and
a third parallel arm connected between the signal line and the ground at outer side of the second series arm, including a series connection of a variable capacitance and an inductance, and constituting a variable series resonator having a variable resonance frequency.

5. The variable filter device according to claim 4, wherein the first and the second series arms determine center frequency of a pass band, and the first, the second and the third parallel arms determine attenuation poles sandwiching the pass band.

6. The variable filter device according to claim 1, wherein at least one of the variable series resonators includes a variable distributed constant line.

7. The variable filter device according to claim 6, wherein the variable distributed constant line includes a transmission line and a variable capacitance which includes the transmission line as one electrode and a counter electrode connected to the ground as another electrode.

8. A variable filter device comprising:
ground conductor serving as earth and a signal line in combination with the ground conductor;
a first series arm forming part of the signal line, including a variable capacitor and an inductance, and constituting a series resonator; and
first and second parallel arms, connected between the signal line and the ground at both sides of the first series arm, each of the first and second parallel arms including a variable capacitor and an inductance, and constituting a grounded series resonator.

9. A variable filter device comprising:
ground conductor serving as earth;
a first filter element including first and second variable capacitances connected in series, and a first series resonator including a series connection of a third variable capacitance and a first inductance, connected between an interconnecting point of the first and the second variable capacitances and the ground conductor; and
a second filter element including second and third inductances connected in series, and a second series resonator including a fourth variable capacitance and a fourth inductance connected between an interconnecting point of the second and the third inductances and the ground conductor;
wherein one of the first and the second variable capacitances of the first filter element and one of the second and the third inductances of the second filter element are connected in series, and constitute a third series resonator.

10. The variable filter device according to claim 9, further comprising:
at least one of a third filter element and a fourth filter element;
wherein the third filter element includes a fifth and sixth inductances connected in series, and connected in series to another of the first and the second variable capacitances of the first filter element, and a fourth series resonator including a series connection of a fifth variable capacitance and a seventh inductance, connected between an interconnection point of the fifth and the sixth inductances and the ground conductor; and
the fourth filter element includes sixth and seventh variable capacitances connected in series, and connected in series to another of the second and the third inductances of the second filter element, and a fifth series resonator including a series connection of a eighth variable capacitor and a eighth inductance, connected between an interconnection point of the sixth and the seventh variable capacitances and the ground conductor.

11. A communication device comprising:
an antenna;
a signal line connected to the antenna; and
a variable band pass filter connected to the signal line,
wherein the variable band pass filter includes:
ground conductor serving as earth;
a first series arm forming part of the signal line and constituting a variable series resonator having a variable resonance frequency; and
first and second parallel arms connected between the signal line and the ground conductor, at both sides of the first series arm in the signal line, and constituting variable series resonators having variable resonance frequencies,
wherein each of the variable series resonators includes a series connection of a variable capacitance and an inductance, or a variable distributed constant line.

12. The communication device according to claim 11, further comprising:
a memory storing plural sets of control parameters depending on a center frequency of a pass band and a bandwidth; and
a control circuit controlling the variable band pass filter via the memory.
